(19) United States
(12) Patent Application Publication
(10) Pub. No.: US 2004/0069339 A1
(43) Pub. Date: Apr. 15, 2004

(54) Thermoelectric cooler having first and second TEC elements with differing physical parameters

(75) Inventor: YuZhong Dai, Orefield, PA (US)

Correspondence Address: HITT GAINES P.C., P.O. BOX 832570, RICHARDSON, TX, 75083, US

(73) Assignee: Agere Systems Inc., Allentown, PA

(21) Appl. No.: 10/268,188

(22) Filed: Oct. 10, 2002

(51) Int. Cl. H01L 37/00; H01L 35/00

(52) U.S. Cl. 136/203

(57) ABSTRACT

The present invention provides a thermoelectric cooler (TEC) In one embodiment, the TEC includes a first substrate and a second substrate. In addition, the TEC includes first and second TEC elements coupled to and between the first substrate and the second substrate. Moreover, the second TEC elements have a physical parameter different from the first TEC elements. A method of manufacturing a TEC and a laser pump module incorporating the TEC or the method are also disclosed.

### TECHNICAL FIELD OF THE INVENTION

The present invention is directed, in general, to thermoelectric devices, and, more specifically, to a thermoelectric cooler (TEC) having first and second TEC elements with a differing physical parameter.

### BACKGROUND OF THE INVENTION

Thermoelectric cooler (TEC) devices have been used for cooling optical devices and in other technology fields. The basic concept behind thermoelectric technology, which allows a TEC to actively transfer (or “pump”) heat through the TEC, is the Peltier effect. The Peltier effect occurs when electrical current flows through two dissimilar conductors. Depending on the direction of current flow, the junction of the two conductors will either absorb or release heat. In TECs, the Peltier effect is used to transfer heat from a “cold side” plate or substrate, where a heat generating device may be mounted, to a “hot side” plate or substrate, where the heat may be dispersed into the ambient using a heat sink coupled thereto. The device employ a group of TEC elements that are configured to transfer the heat in response to a DC voltage. The use of DC voltage forces the heat to pump in only one direction, where AC voltage would simply transfer the heat back and forth in opposing directions.

Typically for TECs, semiconductors (usually bismuth telluride) are the materials of choice for producing the Peltier effect, in part because they may be more easily optimized for pumping heat. In addition, however, semiconductor materials are also chosen because designers are usually more able to control the type of charge carrier employed within the conductor. This is important because heat will be pumped with, and in the direction of, charge carrier movement throughout the circuit. For example, if an n-type semiconductor material is used to fabricate the TEC elements coupling the cold and hot side substrates together, electrons will be the charge carrier employed to create the bulk of the Peltier effect. With a DC voltage source connected to the n-type TEC elements, electrons will be repelled by the negative pole and attracted by the positive pole of the power supply. Thus, heat is effectively pumped by the charge carriers through the semiconductor TEC elements. Similarly, if p-type TEC elements are employed, the charge carriers in the semiconductor material are positive, which are known as “holes.” Such positive charge carriers are repelled by the positive pole of the DC voltage power supply and attracted to the negative pole, thus pumping heat in a direction opposite to that of an n-type TEC elements.

In conventional TECS, a combination of n-type and p-type materials are typically used for the TEC elements, and this combination of TEC elements are electrically coupled in series, but they are thermally coupled in parallel. By coupling all the TEC elements in thermal parallel between a cold side substrate and a hot side substrate, all the TEC elements may be configured to pump heat in the same direction, e.g., from the cold side to the hot side. From this configuration, the heat pumping efficiency of the TEC (e.g., the amount of heat pumped for a given applied voltage) may be increased from a TEC employing only n-type or p-type materials alone.

One particular use of TECs that has gained continued popularity over the years is the use of a TEC to cool a laser assembly within an optical communications network. Typically, a laser generator is located within such a laser assembly, for example, in an optical transmitter. As the laser generator generates optical signals, it also generates an increasing amount of heat. Thus, as output power of the laser generator increases, so too does the amount of heat generated. By mounting the laser generator, along with its complimentary components, in thermal contact with the cold side substrate of a TEC, the TEC may be used to pump heat out of the laser generator and disperse it via a heat sink coupled to the hot side substrate.

As a result, the laser generator is able to operate at a cooler temperature, which in turn, results in a higher output power. For practical optical applications, this becomes especially important in optical amplifiers dispersed along the optical fibers of an optical communications network. Typically, the laser generators found in such optical amplifiers are required to generate higher output power, in order to boost the optical signal during its transmission, than laser generators located in optical transmitters used to originate the signal.

Although a TEC is capable of actively pumping heat away from such optical devices, as opposed to relying on passive devices, such as mounting a heat sink directly thereto, this capability comes at the expense of power consumed by the TEC itself. Unfortunately, the more heat the laser generator creates, the more power is consumed by the TEC in order to cool the laser generator. Conversely, if the power consumption by the TEC is reduced in order to save costs, the less the laser generator is cooled. As a result, since the level of output power generated by the laser generator is substantially proportional to the amount of heat created, its output power must typically be reduced to compensate for the decreased cooling provided by the TEC. Accordingly, what is needed in the art is a TEC that more efficiently cools a laser generator, allowing the laser generator to produce more power for the same amount of power consumed by the TEC.

### SUMMARY OF THE INVENTION

To address the above-discussed deficiencies of the prior art, the present invention provides a thermoelectric cooler (TEC). In one embodiment, the TEC includes a first substrate and a second substrate. In addition, the TEC includes first and second TEC elements coupled to and located between the first substrate and the second substrate. Moreover, the second TEC elements have a spatial relationship different from the first TEC elements.

In another aspect, the present invention provides a method of manufacturing a TEC. In one embodiment, the method includes providing a first substrate and a second substrate. In addition, the method further includes coupling the first substrate to the second substrate with first and second TEC elements. In such an embodiment, the second TEC elements have a spatial relationship different from the first TEC elements.

In yet another aspect, the present invention provides a laser pump module. In one embodiment, the laser pump module includes a laser generator mounted on a submount, and a TEC coupled to the submount. The TEC includes a first substrate and a second substrate. In this embodiment, the TEC also includes first and second TEC elements coupled to and located between the first substrate and the second substrate. Moreover, the second TEC elements have a spatial relationship different from the first TEC elements.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the present invention.

### BRIEF DESCRIPTION OF THE DRAWINGS

For a more complete understanding of the present invention, reference is now made to the following detailed description taken in conjunction with the accompanying FIGUREs. It is emphasized that various features may not be drawn to scale. In fact, the dimensions of various features may be arbitrarily increased or reduced for clarity of discussion. In addition, it is emphasized that some components may not be illustrated for clarity of discussion. Reference is now made to the following descriptions taken in conjunction with the accompanying drawings, in which:

FIG. 1 illustrates a side view of one embodiment of a thermoelectric cooler constructed according to the principles of the present invention;

FIG. 2 illustrates a side view of a second embodiment of a thermoelectric cooler constructed according to the present invention;

FIG. 3 illustrates a side view of a third embodiment of a thermoelectric cooler constructed according to the present invention; and

FIG. 4 illustrates a top view of a high level block diagram of one embodiment of a laser pump module employing a thermoelectric cooler constructed according to the principles of the present invention.

### DETAILED DESCRIPTION

Referring initially to FIG. 1, illustrated is a side view of one embodiment of a thermoelectric cooler (TEC) 100 constructed according to the principles of the present invention. The TEC 100 includes a cold side substrate 110 and a hot side substrate 120. Advantageously, the cold and hot side substrates 110, 120 may be constructed from a conventional material, such as ceramic and using conventional processes. However, it should be understood that other materials know to those who are skilled in the art may also be employed. Those who are skilled in the art understand that the use of materials having ceramic for the cold and hot side substrates 110, 120 provides a beneficial compromise between electrical resistivity and thermal conductivity. In other embodiments, the cold and hot side substrates 110, 120 may be constructed from a material providing greater thermal conductivity for a given electrical resistivity than conventionally available ceramics. Such materials may only be slightly composed of ceramic, or may even be free of ceramic altogether.

The TEC 100 also includes a submount 130 coupled to the cold side substrate 110. The submount 130 may be coupled to the cold side substrate 110 using a conventional thermally conductive adhesive, however other mounting techniques may also be employed. Advantageously, the submount 130 may be constructed from the same material as the material used to construct the cold and hot side substrates 110, 120, however the present invention is not so limited. In an exemplary embodiment, a conventional laser generator, for example, a laser diode, (not illustrated) may be mounted on the submount 130 by adhesive, soldering, or other thermally conductive means. In such an application, the TEC 100 may be employed to draw heat from the laser generator via the submount 130 and cold side substrate 110, and disperse it through the hot side substrate 120. Of course, other heat generating devices may be mounted on the submount 130 in order to beneficially draw the heat therefrom using a TEC constructed according to present invention.

Thermally coupling the cold side substrate 110 and the hot side substrate 120 together are first TEC elements 140 and second TEC elements 150. As shown in an exemplary embodiment of FIG. 1, the first TEC elements 140 may be located in a first temperature zone. More specifically, the physical location of the submount 130 typically results in a significant temperature differential between the area of the cold side substrate 110 proximate the submount 130 and the area of the cold side substrate 110 distal therefrom.

In contrast, the second TEC elements 150 may be located on an outer perimeter of the TEC 100. This location can cause the second TEC elements 150 to be have a lower temperature because they are located more distally from the submount 130. In an advantageous embodiment and for purposes of discussion herein, the TEC elements located in the higher or first temperature zone can include the first TEC elements 140. Likewise, the TEC elements located in the lower or second temperature zone can include the second TEC elements 150. However, it should be noted that other embodiments as covered by the present invention are not limited to this particular designation, and in deed, the temperature zones may vary depending on the location of the submount 130. In addition, as discussed in greater detail below, the temperature gradient between the first and second temperature zones may be graded rather than sharp in transition, providing a gradual temperature differential when moving from one zone to the other.

The first and second TEC elements 140, 150 are electrically coupled together, typically in series, and are also coupled to the terminals of a DC voltage power supply (not illustrated). For example, ends of the first and second TEC elements 140, 150 may be coupled using a good electrical conductor, such as copper or aluminum. In addition, the first and second TEC elements 140, 150 are constructed from semiconductor materials capable of producing the Peltier effect, such as bismuth telluride Bi₂Te₃. Of course, other materials, whether now known or later discovered, may also be used as the TEC elements 140, 150 to create the Peltier effect used to draw heat from the cold side substrate 110 and pump it through to the hot side substrate 120. In an advantageous embodiment, the TEC elements 140, 150 may be arranged in an alternating layout, alternating between adjacent n-type and p-type semiconductor TEC elements. Alternatively, all of the TEC elements 140, 150 may be n-type or p-type semiconductor material, depending on the application of the TEC 100.

The present invention is based, at least, in part on the realization that the temperature differential between the first and second temperature zones impacts the efficiency by which the TEC elements 140, 150 pump heat from the cold side substrate 110 to the hot side substrate 120. More specifically, as touched on above, as a heat producing device mounted on the submount 130 generates heat, that heat tends to be concentrated in the area of the cold side substrate 110 proximate the submount 130, thus creating the first temperature zone. In contrast, the areas of the cold side substrate 110 distal from the submount 130 (and, thus, the heat-generating device) tend to experience a lesser amount of heat based on distance from the heat producing device, thus creating the second temperature zone. As a result, in a conventional TEC, the TEC elements located in the first temperature zone are typically operating at peak efficiency due to the high temperatures proximate the heat-generating device. This typically means they are pumping their maximum amount of heat for a given applied voltage. Unfortunately, however, the TEC elements 150 located in the second temperature zone, and away from the heat-generating device, are typically operating far less efficiently. This is typically the case since they are being operated at the same voltage as the TEC elements 140 in the first temperature zone, and thus consuming the same power as the first TEC elements 140, but have significantly less heat to transfer.

By realizing the disparity in the heat present across the cold side substrate 110, the present invention provides TEC elements that have a different spatial relationship. In the embodiment illustrated in FIG. 1, the different spatial relationship is reflected by a difference in aspect ratio (height to width ratio) between ones of the first and second TEC elements 140, 150. In the exemplary embodiment, the aspect ratio of the second TEC elements 150 is greater than the aspect ratio of the first TEC elements 140. As a result, the width of the second TEC elements 150 is significantly less than that of the first TEC elements 140, although they all have substantially the same height. In one embodiment, the aspect ratio of the second TEC elements 150 may be in the range of about 0.5 to about 1.5 times greater than the aspect ratio of the first TEC elements 140. In yet another embodiment, the aspect ratio is about 1.

The aspect ratio of the second TEC elements 150 may be selected such that enough material is present to pump the heat present in the second temperature zone for a given voltage applied across the entire TEC 100. In another advantageous embodiment, the aspect ratio of each of the second TEC elements 150 may gradually increase when moving in a direction away from the first TEC elements 140. In such an embodiment, the graded aspect ratios of the second TEC elements 150 correspond to the graded decrease in heat when moving from the first temperature zone to the second temperature zone.

By having a greater aspect ratio, the second TEC elements 150 transfer heat from the cold side substrate 110 to the hot side substrate 120 more efficiently than typically found in conventional TECs. Stated another way, the second TEC elements 150 may be operated closer to their peak efficiency per the amount of power consumed by the TEC 100 based on their overall size, as are the first TEC elements 140. By having a lesser width for the same height as the first TEC elements 140, the second TEC elements 150 consume less power, while still transferring the heat present in the second temperature zone of the cold side substrate 110. Since the thermal load in the first temperature zone is relatively higher, due to its close proximity to a heat-generating device, TEC elements having a lesser aspect ratio (e.g., the first TEC elements 140) are needed to transfer this greater amount of heat away from the first temperature zone. However, since the thermal load in the second temperature zone is less, due to its distance from the heat-generating device, TEC elements having a greater aspect ratio (e.g., the second TEC elements 150) are all that are needed for the lesser amount of heat present.

Thus, for the amount of voltage applied across the entire TEC 100, all of the TEC elements 140, 150 operate more efficiently, and perhaps at their peak efficiency, by selecting aspect ratios for the TEC elements based on their location with respect to differing thermal loads on the cold side substrate 110. As a result, in an embodiment where a laser generator is mounted on the submount 130 and cooled by the TEC 100, for the same amount of laser power generated, the TEC 100 of the present invention consumes less total power. Therefore, conversely, for the same amount of power needed to operate a conventional TEC, the TEC 100 of the present invention allows more overall power to be generated by the laser generator, due to the increase in cooling efficiency.

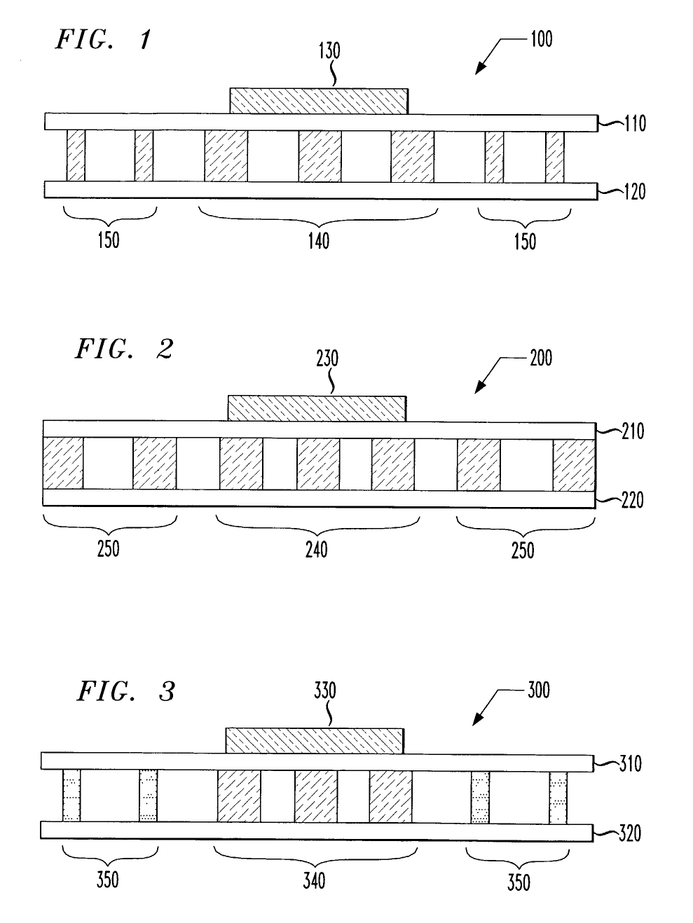

Turning now to FIG. 2, illustrated is a side view of a second embodiment of a TEC 200 constructed according to the present invention. In this embodiment, the TEC 200 still includes a cold side substrate 210 and a hot side substrate 220, and may be constructed as described above. In addition, the TEC 200 still also includes a submount 230 coupled to the cold side substrate 210 for mounting a heat-generating device (not illustrated) on the TEC 200. Furthermore, as with the TEC 100 of FIG. 1, the TEC 200 in FIG. 2 also includes first elements 240. As was the case with the embodiment illustrated in FIG. 1, the first TEC elements 240 may be associated with a first temperature zone proximate the submount 230, and second TEC elements 250 may be associated with a second temperature zone distal the submount 230. The first and second TEC elements 240, 250 may be constructed and arranged in the manner described above with respect to FIG. 1, however the present invention is not so limited.

The embodiment illustrated in FIG. 2 differs from the TEC 100 in FIG. 1 in that the first and second TEC elements 240, 250 are constructed having substantially the same aspect ratio. However, the spatial relationship between each of the second TEC elements 250 differs from that of the first TEC elements 240. More specifically, as illustrated, the spacing between each of the second TEC elements 250, as well as between adjacent ones of the first and second TEC elements 240, 250, is greater than the spacing between each of the first TEC elements 240. Thus, the difference in spatial relationship is the physical parameter of the second TEC elements 240 that differs from the first TEC elements 250.

As discussed above, the thermal load associated with the first temperature zone is greater than that associated with the second temperature zone, due primarily to the positioning of a heat-generating device on the submount 230. As a result, a greater number of otherwise similar TEC elements should be located in the first temperature zone than in the second temperature zone since, for a given set of conditions, a greater number of TEC elements can transfer more heat than a lesser number. Conversely, a greater number of otherwise similar TEC elements can transfer the same amount of heat as a lesser number, but in less time. Thus, in this embodiment, the present invention provides a TEC 200 having a greater concentration of TEC elements in the first temperature zone, and a lesser concentration in the second temperature zone, by providing a greater spatial relationship between each of the second TEC elements 250 when compared to that of the first TEC elements 240. It should be understood that the submount 230 may be located at various positions on the cold side substrate 210.

In a more specific embodiment, the spacing between each of the second TEC elements 250 is in the range of about 1.0 to about 1.5 mm, while the spacing between each of the first TEC elements 240 is in the range of about 0.5 to about 1.0 mm. With a greater spatial relationship between the second TEC elements 250, the resulting lesser concentration of second TEC elements 250 allows them to operate closer to their peak efficiency, since the thermal load is proportionately lower in the second temperature zone. Thus, the transfer of heat from the cold side substrate 210 to the hot side substrate 220 occurs more efficiently for the amount of voltage applied to the TEC 200, since both the first and second TEC elements 240, 250 are operated nearer their peak efficiency.

Also as illustrated in FIG. 2, the spatial relationship between each of the second TEC elements 250 may be increased progressively as the distance from the submount 230 increases. Such a progressive increase may provide even greater efficiency in the transfer of heat from the cold side substrate 210, since the amount of heat on the cold side substrate 210 gradually decreases when moving away from the submount 230 and the heat-generating device mounted thereon. As a result, the concentration of TEC elements needed to transfer the gradually decreasing heat also gradually decreases when moving away from the submount 230.

Accordingly, rather than operating a large number of second TEC elements 250 at less than peak efficiency, a lesser concentration of second TEC elements 250 may move the same amount of heat more efficiently, since a lesser number of TEC elements consumes less power. By adjusting the spatial relationship of the TEC elements 240, 250 is this manner, the TEC 200 may be configured to consume less total power for the amount power generated by, for example, a laser generator used in optical applications, when compared to conventional TECs. Conversely, a greater overall power generated by a laser generator may be had for the same amount of power needed to operate the TEC 200.

Turning to FIG. 3, the chemical composition of the second TEC elements 350 may also differs from that of the first TEC elements 340 in addition to having a different spatial relationship as discussed above. The materials from which these TEC elements are constructed are know to those who are skilled in the art. For example, the first TEC elements 340 may be constructed from a Z-material or F-material that is provided by Komatsu Electronics, Inc., 2597 Shinomiya, Hiratsuka-shi, Kanagawa-ken, Japan, while the second TEC elements 350 is made from either the Z-material or F-material that is not selected for the first TEC elements' 340 construction. Alternatively, the first TEC elements may be made from aluminum oxide ceramics or beryllium oxide ceramics, which is a combination of aluminum oxide and beryllium, while the second TEC elements may be made from either of these materials that is not selected for the first TEC elements' 340 construciton.

In addition to the difference in spatial relationships, the difference in chemical composition allows the second TEC elements 350 to transfer a different amount of heat from the cold side substrate 310 to the hot side substrate 320, for a given applied voltage, based on a degree of the Peltier effect generated by the selected materials. More specifically, since the thermal load associated with the first temperature zone is typically greater than that associated with the second temperature zone, the material used to construct the first TEC elements 340 should allow the first TEC elements 340 to transfer a greater amount of heat than that used for the second TEC elements 350, for an amount of power consumed. Conversely, the second TEC elements 350 may be constructed of a material configured to operate near peak efficiency when consuming less power than the first TEC elements 340, but still transferring the lesser amount of heat present in the second temperature zone.

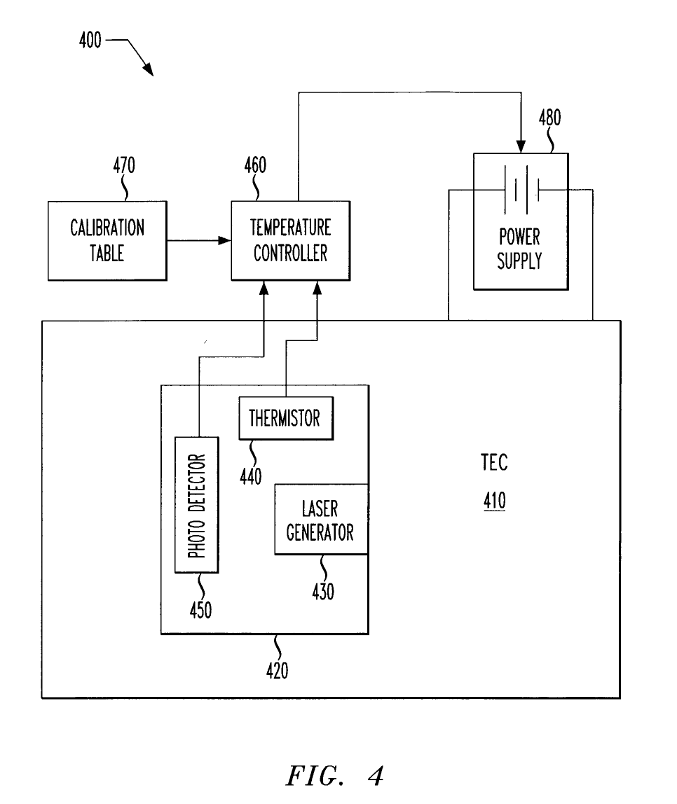

Turning finally to FIG. 4, illustrated is a top view of a high level block diagram of one embodiment of a laser pump module 400 employing a TEC 410 constructed according to the principles of the present invention. Mounted on the TEC 410 is a submount 420 configured to carry operative components of the laser pump module 400. As in other embodiments of the present invention, the submount 420 may be thermally coupled to a cold side substrate (not separately designated) of the TEC 410, as described above.

The laser pump module 400 includes a laser generator 430 for generating an optical signal to be transmitted across an optical communications network (not illustrated). Alternatively, the laser generator 430 may be used to amplify an existing optical signal traversing the optical network. Also mounted on the submount 420 is a thermistor 440, which may be used to monitor the operating temperature of the laser generator 430. Of course, other appropriate temperature monitoring devices may also be used. A photodetector 450 is also shown mounted on the submount 450. In accordance with conventional practice, the laser generator 430 outputs an optical signal from both ends, one for optical transmission and one for monitoring the output of the laser generator 430. The photodetector 450 is configured to receive the output used to monitor the laser generator 430 and transmits a signal to a temperature controller 460 in response thereto. In addition, the monitored temperature of the laser generator 430 is also fed to the temperature controller 460 via the thermistor 440.

The temperature controller 460 is used to activate the TEC 410 in order to cool the laser generator 430 when desired, allowing the laser pump module 400 to operate more efficiently. The temperature controller 460 may accomplish this by employing the signals transmitted by the thermistor 440 and the photodetector 450, as well as information provided by a calibration table 470. Since the efficiency of the laser generator 430 is typically a function of its temperature, the controller 460 and the devices providing the input signals thereto provide a temperature control system used to cool the laser generator 430, as well as to control the wavelength of its output, by activating the TEC 410.

The calibration table 470 contains several data points generated by observing the various outputs produced by the laser generator 430, temperatures detected by the thermistor 440, and signals generated by the photodetector 450. In operation, a signal from the photodetector 450 is compared to the values in the calibration table 470, which then causes the temperature controller 460 to transmit an error signal to a DC voltage power supply 480 coupled to the TEC 410. The DC voltage applied to the TEC 410 through the power supply 480 may then be altered, using the error signal from the temperature controller 460, causing the TEC 410 to pump a greater or lesser amount of heat away from the components mounted on the submount 420.

Specifically, the heat is pumped through first and second TEC elements (not illustrated) within the TEC 410 that have been constructed according to the present invention, in the manner described above in greater detail. After being transmitted through the TEC elements, the heat may then be dispersed into the ambient via a heat sink (not illustrated) coupled to the hot side substrate of the TEC 410. Of course, it should be noted that a laser pump assembly having a TEC constructed according to the present invention is not limited to the components illustrated in FIG. 4, and may include other components as each application requires.

By providing a TEC with first and second TEC elements having at least one different physical parameter, the present invention provides for a more efficient removal of heat when compared to conventional TECs. For instance, when used with the laser pump module 400 in an optical communications system, less power is consumed by the TEC 410 for a given amount of power generated by a laser generator 430. This is accomplished by selecting different physical parameters for the TEC elements based on the thermal load on different portions of the TEC 410, thus more efficiently transferring heat from the laser generator 430 and allowing it to operate more efficiently. As a result, by providing a TEC constructed according to the principles described herein, for the same amount of power consumed by the TEC 410, more overall power may be generated by the laser generator 430.

Those who are skilled in the art understand that the more efficient the operation of a laser pump module, the lower the overall operation costs of the optical communications network incorporating the module. Furthermore, a TEC according to the present invention is employable any part of an optical communications network heat removal is desired. For example, the novel TEC may not only be incorporated in a laser pump module for use in boosting an optical signal during transmission across an optical network, but may also be employed in an optical transmitter used to originate the optical signal, while still overcoming the deficiencies of prior art TECs. Moreover, a TEC according to the present invention is employable in almost any situation where the active removal of heat is critical, and is not just limited to use in optical devices and networks.

To demonstrate the increased efficiency of a TEC constructed according to the principles described herein, a mathematical model may be. To this end, the efficiency of a TEC may be measured by a “Coefficient of Performance” (COP). The COP of a TEC element, as used herein, is defined as the amount of useful cooling (e.g., the amount of heat pumped) divided by the input power.

Mathematically, the COP for a single TEC element may be expressed as set forth in equation (1). Table 1 sets for the variables used with equation (1). As shown in equation (1), the COP is a function of ΔT, which is the temperature differential between the hot and cold sides of a TEC.

TABLE 1

| | |
|---|---|
| | (I) |
| $COP = \frac{{q}_{c}}{w} = \frac{α \cdot I \cdot {T}_{c} - λ \cdot ( A / L ) \cdot ΔT - 0.5 \cdot {I}^{2} \cdot ρ \cdot ( L / A )}{α \cdot I \cdot ΔT + {I}^{2} \cdot ρ \cdot ( L / A )}$ | |

| VARIABLE | VARIABLE DEFINED |
|---|---|
| q_{c} | heat pumped by TEC element |
| w | power consumption of TEC element |
| α | Seebeck coefficient of material of |
| | TEC element |
| I | current through TEC element |
| T_{c} | cold side temperature |
| λ | thermal conductivity of TEC element |
| A | cross section area of TEC element |
| L | length of TEC element |
| ΔT | temperature differential between the |
| | hot and cold side substrates of TEC |
| ρ | electrical resistivity of TEC element |

Equation (1) may also be used to show that for applications having a heat load concentrated at the center of the cold side of a TEC, as discussed above, ΔT differs significantly for each TEC element within the TEC. For example, assume ΔT equals 40° for a central TEC element and 30° for the outer TEC elements, in a TEC having only three, otherwise equivalent, TEC elements. In this example, the COP for the center versus the outer TEC elements peaks at 0.9 versus 0.5. Using equation (1), these peaks require 1.25A and 1.75A of drive current, respectively.

Once the drive current has been determined, and understanding that power is equal to voltage times current (P=V×I) for each TEC element, the overall power consumption (in Watts) of all the TEC elements, and thus the TEC as a whole may be made. Thus, if both the center and outer TEC elements were driven at the same 1.75A in order to maintain the 40° temperature differential, the total power consumption for the TEC, assuming all 3 TEC elements are connected in parallel and operated at 0.1 volt, is:

3×1.75A×0.1V=0.525 W

Conversely, the aspect ratios of the two outer TEC elements may be adjusted to make the outer TEC elements narrower than the center TEC element. This change in aspect ratio causes the electrical resistance of the outer TEC elements to increase so that the drive current is kept at 1.25A. As a result, the power consumption of the TEC (w), still assume a constant 0.1 volts across all the TEC elements, is:

(1.75A×0.1V)+(2×1.25A×0.1V)=0.425 W

As may be seen by this example of a TEC constructed according to the principles of the present invention, a reduction in TEC power consumption from 0.525W to 0.425W results in a 19% reduction in power consumption over a conventional TEC. Moreover, such a reduction in power consumption is not limited to embodiments having different aspect ratios among the TEC elements, but may also be had in embodiments where one or more of the physical parameters of the TEC elements distal the heat-generating device are different than those of the TEC elements located near the device.

Although the present invention has been described in detail, those skilled in the art should understand that they can make various changes, substitutions and alterations herein without departing from the spirit and scope of the invention in its broadest form.

What is claimed is:

1. A thermoelectric cooler (TEC), comprising:
a first substrate;
a second substrate; and
first and second TEC elements coupled to and located between said first substrate and said second substrate, said second TEC elements having a spatial relationship different from a spatial relationship of said first TEC elements.

2. The TEC as recited in claim 1 wherein a chemical composition of said second TEC elements is different from a chemical composition of said first TEC elements.

3. The TEC as recited in claim 1 wherein an aspect ratio of said second TEC elements is different from an aspect ratio of said first TEC elements.

4. The TEC as recited in claim 3 wherein said aspect ratio of said second TEC elements increases in a direction away from said first TEC elements.

5. The TEC as recited in claim 1 wherein said second TEC elements are located on an outer perimeter of said TEC.

6. The TEC as recited in claim 1 wherein said TEC forms at least a portion of a laser pump module, said laser pump module further including a laser generator thermally coupled to said TEC.

7. The TEC as recited in claim 1 wherein said second TEC elements are located in a different temperature zone than said first TEC elements.

8. A method of manufacturing a thermoelectric cooler (TEC), comprising:
providing first and second substrates; and
coupling said first substrate to said second substrate with first and second TEC elements, said second TEC elements having a spatial relationship different from said first TEC elements.

9. The method as recited in claim 8, wherein said coupling includes coupling with second TEC elements having a chemical composition different from said first TEC elements.

10. The method as recited in claim 8, wherein said coupling includes coupling with second TEC elements having an aspect ratio different from said first TEC elements.

11. The method as recited in claim 8 wherein said aspect ratio of said second TEC elements increases in a direction away from said first TEC elements.

12. The method as recited in claim 8 wherein said coupling includes coupling said second TEC elements at an outer perimeter of said first and second substrates.

13. The method as recited in claim 8 wherein said coupling further includes thermally coupling said first substrate to a laser generator to form at least a portion of a laser pump assembly.

14. The method as recited in claim 8 wherein coupling includes couple said second TEC elements in a different temperature zone than said first TEC elements.

15. A laser pump module, comprising:
a laser generator mounted on a submount; and
a thermoelectric cooler (TEC), coupled to said submount, including:
a first substrate,
a second substrate, and
first and second TEC elements coupled to and located between said first substrate and said second substrate, said second TEC elements having a spatial relationship different from a spatial relationship of said first TEC elements wherein a distance between said second TEC elements ranges from about 1.0 mm to about 1.5 mm.

16. The laser pump module as recited in claim 15 wherein a chemical composition of said second TEC elements is different from said first TEC elements.

17. The laser pump as recited in claim 15 wherein a spacing between said first TEC elements ranges from about 0.5 mm to about 1.0 mm.

18. The laser pump as recited in claim 15 wherein an aspect ratio of said second TEC elements ranges from about 0.5 to about 1.5 times greater than an aspect ratio of said first TEC elements.

19. The laser pump as recited in claim 3 wherein said aspect ratio of said second TEC elements increases in a direction away from said first TEC elements.

20. The laser pump as recited in claim 15 wherein said second TEC elements are located in a different temperature zone than said first TEC elements.
